(19) United States
(12) Patent Application Publication
(10) Pub. No.: US 2023/0041754 A1
(43) Pub. Date: Feb. 9, 2023

(54) PROCESSING APPARATUS AND VIBRATION DETECTING METHOD

(71) Applicant: DISCO CORPORATION, Tokyo (JP)

(72) Inventors: Hiroto YOSHIDA, Tokyo (JP); Nobuyasu KITAHARA, Tokyo (JP); Tasuku KOJO, Tokyo (JP)

(21) Appl. No.: 17/813,438

(22) Filed: Jul. 19, 2022

(30) Foreign Application Priority Data
Aug. 4, 2021 (JP) 2021-128195

(51) Int. Cl. G01N 21/95; G01N 21/88; G01H 9/00

(52) U.S. Cl. CPC G01N 21/9501; G01N 21/8851; G01H 9/00

(57) ABSTRACT

In a processing apparatus, a vibration detecting unit includes a light source, an interference unit configured to apply light emitted from the light source to a measurement target member and generate an interference pattern image. A control unit includes a storage section configured to store a first interference pattern image captured at a predetermined timing by the imaging unit and a second interference pattern image captured at a timing different from the timing of the first interference pattern image by the imaging unit, a comparing section configured to compare the first interference pattern image and the second interference pattern image stored in the storage section with each other, and a vibration detecting section configured to detect vibration on the basis of the first interference pattern image and the second interference pattern image compared with each other by the comparing section.

### BACKGROUND OF THE INVENTION

### Field of the Invention

The present invention relates to a processing apparatus and a vibration detecting method.

### Description of the Related Art

A semiconductor wafer having a plurality of devices formed on a top surface thereof is formed into chips by being divided along streets set on the top surface by a processing apparatus such as a dicing apparatus or a laser processing apparatus (see Japanese Patent Laid-Open No. 2001-007058 and Japanese Patent Laid-Open No. 2003-320466).

### SUMMARY OF THE INVENTION

In a case where the wafer is processed by using the processing apparatus described above, there is a possibility of occurrence of a division defect and a decrease in yield when a processing depth is insufficient. Hence, suppressing vibration in the depth direction of the wafer, that is, a Z-axis direction, is a very important challenge. Conventionally, however, it is difficult to determine a cause of the vibration in the Z-axis direction in the processing apparatus or identify a part causing the vibration.

It is accordingly an object of the present invention to provide a processing apparatus and a vibration detecting method that can detect vibration of the apparatus in a height direction of a workpiece as a processing target.

In accordance with an aspect of the present invention, there is provided a processing apparatus including a holding unit configured to hold a workpiece, a processing unit configured to process the workpiece held by the holding unit, a moving unit configured to move the holding unit and the processing unit relative to each other, a vibration detecting unit, and a control unit configured to control the holding unit, the processing unit, the moving unit, and the vibration detecting unit. The vibration detecting unit includes a light source, an interference unit configured to apply light emitted from the light source to a measurement target member and generate an interference pattern image including an interference pattern of the measurement target member, and an imaging unit configured to capture the interference pattern image of the measurement target member, the interference pattern image being generated by the interference unit. The control unit includes a storage section configured to store a first interference pattern image captured at a predetermined timing by the imaging unit and a second interference pattern image captured at a timing different from the timing of the first interference pattern image by the imaging unit, a comparing section configured to compare the first interference pattern image and the second interference pattern image stored in the storage section with each other, and a vibration detecting section configured to detect vibration on the basis of the first interference pattern image and the second interference pattern image compared with each other by the comparing section.

Preferably, the control unit further includes a three-dimensional image generating section configured to generate a three-dimensional image of the measurement target member on the basis of a plurality of interference pattern images captured while a position of the imaging unit is changed in a direction parallel with an imaging direction. Preferably, the measurement target member is the holding unit configured to hold the workpiece.

In accordance with another aspect of the present invention, there is provided a vibration detecting method for detecting vibration, the vibration detecting method including a light applying step of irradiating a measurement target member with light, an imaging step of capturing an interference pattern image including an interference pattern generated by interference between reflected light obtained by the light being branched into two light fluxes and one light flux of the two branched light fluxes being reflected by the measurement target member and reference light generated from the other light flux, a storing step of storing the interference pattern image captured in the imaging step, a comparing step of comparing a first interference pattern image captured at a predetermined timing with a second interference pattern image captured at a timing different from the timing of the first interference pattern image, and a vibration detecting step of detecting vibration on the basis of the first interference pattern image and the second interference pattern image compared with each other in the comparing step.

Preferably, the measurement target member has a target pattern, the imaging step captures an interference pattern image including the target pattern, and the comparing step further compares a position of a first target pattern in the first interference pattern image captured at the predetermined timing with a position of a second target pattern in the second interference pattern image captured at the timing different from the timing of the first interference pattern image.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a configuration of a processing apparatus according to an embodiment of the present invention;

FIG. 2 is a sectional view illustrating an example of a configuration of a vibration detecting unit included in the processing apparatus illustrated in FIG. 1;

FIG. 3 is a schematic diagram illustrating an example of a configuration of an interference unit included in the vibration detecting unit illustrated in FIG. 2;

FIG. 4 is a diagram illustrating an example of a first interference pattern image captured at a predetermined timing;

FIG. 5 is a diagram illustrating an example of a second interference pattern image captured at a timing different from that of FIG. 4;

FIG. 6 is a diagram illustrating an example of a first interference pattern image captured at a predetermined timing;

FIG. 7 is a diagram illustrating an example of a second interference pattern image captured at a timing different from that of FIG. 6;

FIG. 8 is a side view illustrating a state in which interference pattern images for obtaining a three-dimensional image are being captured;

FIG. 9 is a diagram illustrating an example of the three-dimensional image generated on the basis of the interference pattern images captured in FIG. 8; and

FIG. 10 is a flowchart diagram illustrating a flow of a vibration detecting method according to the embodiment.

### DETAILED DESCRIPTION OF THE PREFERRED EMBODIMENT

The embodiment of the present invention will hereinafter be described in detail with reference to the drawings. The present invention is not limited by contents described in the following embodiment. In addition, constituent elements described in the following include constituent elements readily conceivable by those skilled in the art and essentially identical constituent elements. Further, configurations described in the following can be combined with each other as appropriate. In addition, various omissions, replacements, or modifications of configurations can be performed without departing from the spirit of the present invention.

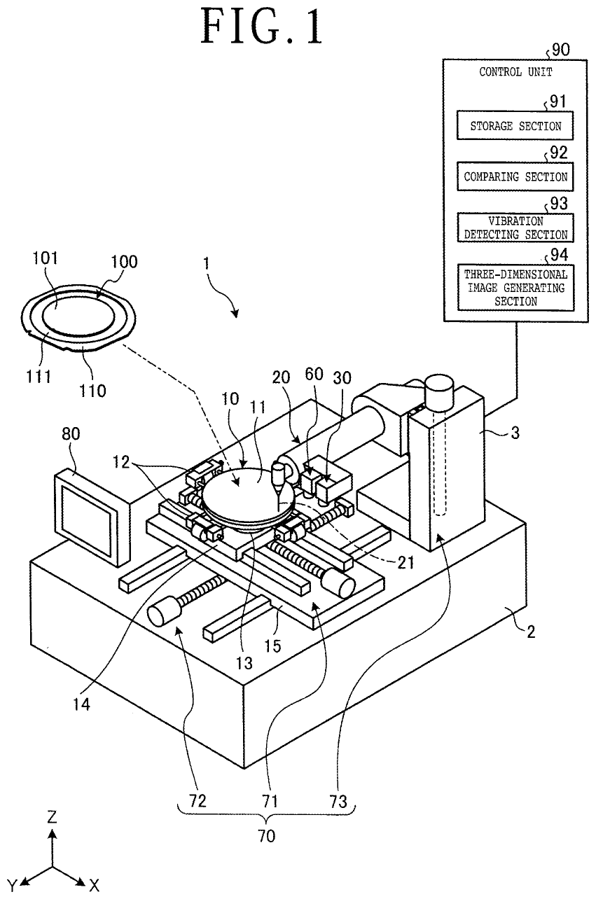

A configuration of a processing apparatus 1 according to an embodiment of the present invention will first be described with reference to the drawings. FIG. 1 is a perspective view illustrating an example of a configuration of the processing apparatus 1 according to the embodiment. In the following description, an X-axis direction is one direction in a horizontal plane. A Y-axis direction is a direction orthogonal to the X-axis direction in the horizontal plane. A Z-axis direction is a direction orthogonal to the X-axis direction and the Y-axis direction. In the processing apparatus 1 according to the embodiment, a processing feed direction corresponds to the X-axis direction, and an indexing feed direction corresponds to the Y-axis direction.

The processing apparatus 1 according to the embodiment illustrated in FIG. 1 is a laser processing apparatus. The processing apparatus 1 includes a holding unit 10, a processing unit 20, a vibration detecting unit 30, an alignment unit 60, a moving unit 70, a display unit 80, and a control unit 90. The processing apparatus 1 according to the embodiment is an apparatus that processes a workpiece 100 held by the holding unit 10 by irradiating the workpiece 100 with a laser beam 21 by the processing unit 20. The processing of the workpiece 100 by the processing apparatus 1 is, for example, modified layer formation processing of forming a modified layer within the workpiece 100 by stealth dicing, groove processing of forming grooves in a top surface 101 of the workpiece 100, or cutting processing of cutting the workpiece 100 along planned dividing lines.

The workpiece 100 in the embodiment is a wafer such as a semiconductor device wafer or an optical device wafer in a disk shape which uses silicon (Si), sapphire (Al₂O₃), gallium arsenide (GaAs), silicon carbide (SiC), lithium tantalate (LiTa₃), or the like as a substrate. A measurement target member to be measured by the vibration detecting unit 30 to be described later may be the workpiece 100. It is to be noted that the workpiece 100 is not limited to the example in the embodiment and may not be in a disk shape in the present invention. A tape 111 to which an annular frame 110 is affixed and which has a diameter larger than an outside diameter of the workpiece 100, for example, is affixed to an undersurface of the workpiece 100, so that the workpiece 100 is supported within an opening of the frame 110.

The holding unit 10 holds the workpiece 100 by a holding surface 11. The holding surface 11 is of a disk shape formed of porous ceramics or the like. The holding surface 11 in the embodiment is a flat surface parallel with a horizontal direction. The holding surface 11 is, for example, connected to a vacuum suction source via a vacuum suction path. The holding unit 10 holds under suction the workpiece 100 placed on the holding surface 11. The measurement target member to be measured by the vibration detecting unit 30 to be described later may be the holding unit 10.

A plurality of clamps 12 that hold the frame 110 supporting the workpiece 100 are arranged on the periphery of the holding unit 10. The holding unit 10 is rotated about an axis parallel with the Z-axis direction by a rotating unit 13. The rotating unit 13 is supported by an X-axis direction movable plate 14. The rotating unit 13 and the holding unit 10 are moved in the X-axis direction by an X-axis direction moving unit 71 of the moving unit 70 via the X-axis direction movable plate 14. The rotating unit 13 and the holding unit 10 are moved in the Y-axis direction by a Y-axis direction moving unit 72 of the moving unit 70 via the X-axis direction movable plate 14, the X-axis direction moving unit 71, and a Y-axis direction movable plate 15.

The processing unit 20 is a unit that processes the workpiece 100 held by the holding unit 10. The processing unit 20 in the embodiment is a laser beam irradiating unit that irradiates the workpiece 100 held by the holding unit 10 with the pulsed laser beam 21 having a predetermined wavelength for processing the workpiece 100. The laser beam irradiating unit, for example, includes a laser oscillator that emits the laser beam 21, a condenser, and various kinds of optical parts provided on an optical path of the laser beam 21 between the laser oscillator and the condenser. The condenser condenses the laser beam 21 emitted from the laser oscillator and propagated through the various kinds of optical parts onto the workpiece 100 held on the holding surface 11 of the holding unit 10. The condenser thus makes the workpiece 100 irradiated with the laser beam 21.

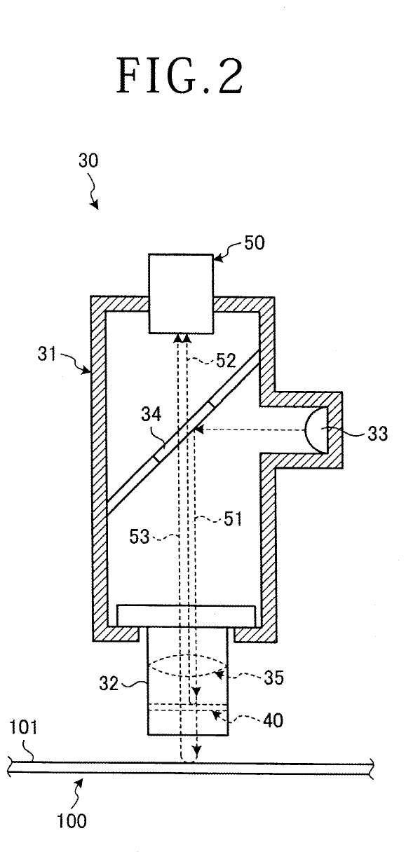

The vibration detecting unit 30 is a unit that detects vibration caused by a motor, a pump, and the like of the processing apparatus 1. The vibration detecting unit 30 at least detects vibration in the Z-axis direction of the processing apparatus 1. The vibration detecting unit 30 may detect vibration in an X-Y plane direction of the processing apparatus 1. As illustrated in FIG. 2, the vibration detecting unit 30 includes a casing 31 including various constituent elements, a lens barrel 32 provided at a lower end of the casing 31, a light source 33, a half-silvered mirror 34, a condensing unit 35, an interference unit 40, and an imaging unit 50.

The light source 33 is provided on an inner side surface of the casing 31. The light source 33 is, for example, a light emitting diode (LED). However, a laser diode (LD) having a predetermined wavelength may be used as the light source 33. The light source 33 applies light 51 to the measurement target member (which is, for example, the holding unit 10 or the workpiece 100 and is the workpiece 100 in the embodiment). The light 51 produced by the light source 33 in the embodiment is emitted mainly toward the half-silvered mirror 34 disposed on a side of the light source 33.

The half-silvered mirror 34 is provided within the casing 31 and on the side of the light source 33. The half-silvered mirror 34 reflects the light 51 produced by the light source 33 toward the measurement target member disposed on the lower side. The half-silvered mirror 34 allows passage therethrough of reflected light 53 reflected by the top surface 101 of the measurement target member (the workpiece 100) and reference light 52 generated by the interference unit 40 to be described later, from the lower side toward the imaging unit 50 disposed on the upper side, which imaging unit will be described later.

The condensing unit 35 condenses the light 51 from the light source 33 onto the top surface 101 of the measurement target member (the workpiece 100). The condensing unit 35 in the embodiment is provided below the half-silvered mirror 34 and is fixed to the inside of the lens barrel 32. The condensing unit 35 in the embodiment condenses the light 51 reflected by the half-silvered mirror 34 onto the top surface 101 of the measurement target member (the workpiece 100). The condensing unit 35 is a convex lens, for example.

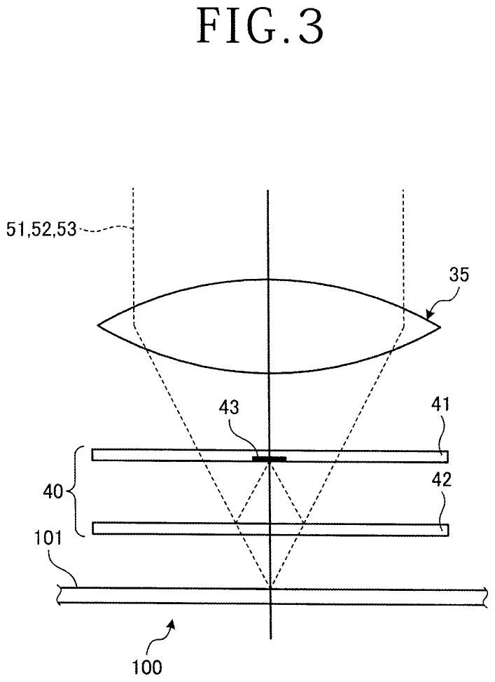

The interference unit 40 is provided below the condensing unit 35. The interference unit 40 generates the reference light 52 for reference. The interference unit 40 makes the reference light 52 interfere with the reflected light 53 of the light 51 reflected by the top surface 101 of the measurement target member (the workpiece 100). The interference unit 40 in the embodiment includes a Mirau interference optical system. However, the interference unit 40 in the present invention may include a Michelson interference optical system. As illustrated in FIG. 3, the interference unit 40 in the embodiment includes a plate 41, a half-silvered mirror 42, and a reference mirror 43.

The plate 41 is formed of a material such as glass that transmits the light 51, the reference light 52, and the reflected light 53. The half-silvered mirror 42 is provided below the plate 41. The half-silvered mirror 42 branches the light 51 from the light source 33 into two light fluxes. The half-silvered mirror 42 guides one light flux of the two branched light fluxes to the measurement target member (for example, the workpiece 100) side and guides the other light flux to the reference mirror 43 side. The reference mirror 43 is a minute mirror disposed at the center of the plate 41. The reference mirror 43 constitutes a reference surface in the plate 41.

The light 51 produced by the light source 33 and reflected downward by the half-silvered mirror 34 passes through the condensing unit 35 and the plate 41 and is partly reflected upward by the half-silvered mirror 42. The part of the light 51 reflected upward by the half-silvered mirror 42 is reflected downward by the reference mirror 43 and is reflected upward by the half-silvered mirror 42 again. This light reflected downward by the reference mirror 43 and reflected upward by the half-silvered mirror 42 again will be referred to as the reference light 52.

Meanwhile, another part of the light 51 having passed through the half-silvered mirror 42 is reflected upward as the reflected light 53 by an inspection target surface (the top surface 101) of the measurement target member (the workpiece 100). The reflected light 53 passes through the half-silvered mirror 42. Together with the reference light 52 reflected upward by the half-silvered mirror 42, the reflected light 53 passes through the plate 41, the condensing unit 35, and the half-silvered mirror 34 and reaches the imaging unit 50 disposed on the upper side.

That is, the interference unit 40 generates an interference image by a difference between an optical path of the reference light 52 as the reflected light from the reference mirror 43 and an optical path of the reflected light 53 as the reflected light from the measurement target member (the workpiece 100). The reference light 52 and the reflected light 53 reaching the imaging unit 50 interfere with each other under predetermined conditions according to a distance from the inspection target surface (the top surface 101 of the workpiece 100) to the interference unit 40 or the like.

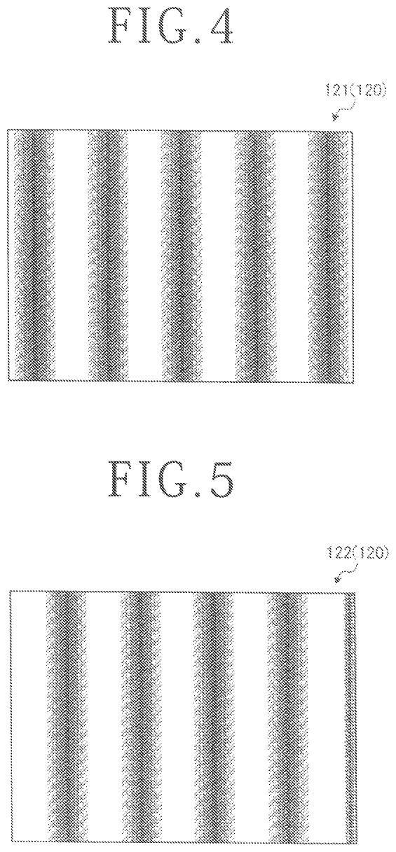

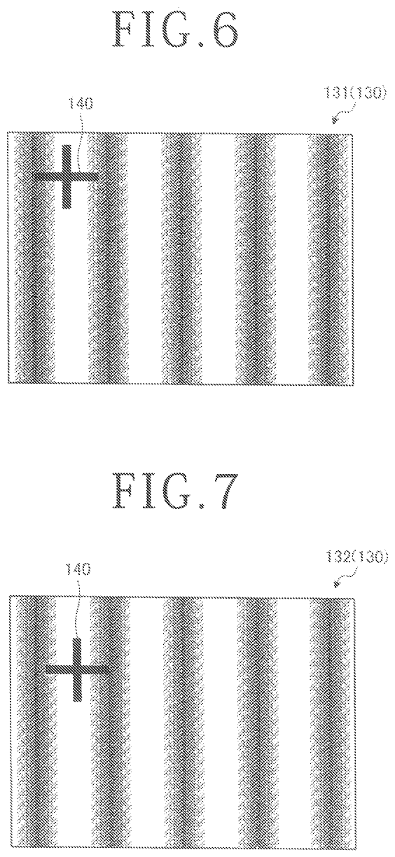

The imaging unit 50 captures interference pattern images 120 and 130 (see FIG. 4, FIG. 5, FIG. 6, and FIG. 7) including an interference pattern generated by interference between the reference light 52 and the reflected light 53 reflected by the measurement target member (the workpiece 100). The imaging unit 50 includes an imaging element such as a charge coupled device (CCD) imaging element or a complementary metal oxide semiconductor (CMOS) imaging element in which a plurality of pixels are arranged two-dimensionally (in the X-axis direction and the Y-axis direction). Because the imaging element images the two-dimensional light intensity of interference light between the reference light 52 and the reflected light 53, the imaging unit 50 can capture the interference pattern images 120 and 130 having a luminance distribution. An imaging direction of the imaging unit 50 is the Z-axis direction, that is, a vertical direction, and is downward.

The light intensity imaged by the imaging element depends on the distance from the inspection target surface (the top surface 101 of the workpiece 100) to the interference unit 40 or the like. That is, the luminance of the captured interference pattern images 120 and 130 changes according to the position in the Z-axis direction of the vibration detecting unit 30. By using this phenomenon, the imaging unit 50 can determine that there is vibration in the Z-axis direction when respective high luminance regions and low luminance regions in the plurality of interference pattern images 120 and 130 captured at different timings are different in a state in which the imaging unit 50 is fixed in the X-axis, Y-axis, and Z-axis directions, for example.

In addition, the imaging unit 50 can form a three-dimensional image 150 (see FIG. 9 and the like) corresponding to the shape of the inspection target surface (the top surface 101 of the workpiece 100) by, for example, extracting coordinates (X-Y coordinates) at which luminance or a luminance change is a maximum from each of a plurality of interference pattern images captured while the position in the Z-axis direction of the imaging unit 50 is changed. That is, the imaging unit 50 in the embodiment includes a three-dimensional profiler mounted in the laser processing apparatus or the like.

The alignment unit 60 includes an imaging unit that images the workpiece 100 held by the holding unit 10, in order to carry out alignment that aligns the workpiece 100 and the processing unit 20 with each other. The imaging unit, for example, includes a CCD camera or an infrared camera. The alignment unit 60 is, for example, fixed in such a manner as to be adjacent to the condenser of the processing unit 20. The alignment unit 60 images the workpiece 100 to obtain an image to be used to carry out the alignment that aligns the workpiece 100 and the processing unit 20 with each other, and outputs the obtained image to the control unit 90.

The moving unit 70 moves the holding unit 10 and the processing unit 20 relative to each other. More specifically, the moving unit 70 moves the holding unit 10 and a processing point of the processing unit 20 (a condensing point of the laser beam 21 in the embodiment) relative to each other. The moving unit 70 further moves the holding unit 10 and the vibration detecting unit 30 relative to each other. The moving unit 70 includes the X-axis direction moving unit 71, the Y-axis direction moving unit 72, and a Z-axis direction moving unit 73.

The X-axis direction moving unit 71 is a unit that moves the holding unit 10 and the processing unit 20 relative to each other in the X-axis direction as the processing feed direction. The X-axis direction moving unit 71 in the embodiment moves the holding unit 10 in the X-axis direction. The X-axis direction moving unit 71 in the embodiment is installed above an apparatus main body 2 of the processing apparatus 1. The X-axis direction moving unit 71 supports the X-axis direction movable plate 14 movably in the X-axis direction.

The Y-axis direction moving unit 72 is a unit that moves the holding unit 10 and the processing unit 20 relative to each other in the Y-axis direction as the indexing feed direction. The Y-axis direction moving unit 72 in the embodiment moves the holding unit 10 in the Y-axis direction. The Y-axis direction moving unit 72 in the embodiment is installed on the apparatus main body 2 of the processing apparatus 1. The Y-axis direction moving unit 72 supports the Y-axis direction movable plate 15 movably in the Y-axis direction.

The Z-axis direction moving unit 73 is a unit that moves the holding unit 10 and the processing unit 20 relative to each other in the Z-axis direction as a focus position adjusting direction. The Z-axis direction moving unit 73 in the embodiment moves at least the condenser in the processing unit 20 in the Z-axis direction. In addition, the Z-axis direction moving unit 73 in the embodiment moves the vibration detecting unit 30 in the Z-axis direction. The Z-axis direction moving unit 73 in the embodiment is installed on a column 3 erected from the apparatus main body 2 of the processing apparatus 1. The Z-axis direction moving unit 73 supports at least the condenser in the processing unit 20 movably in the Z-axis direction.

The X-axis direction moving unit 71, the Y-axis direction moving unit 72, and the Z-axis direction moving unit 73 each include a well-known ball screw, a well-known pulse motor, and well-known guide rails. The ball screw is provided in such a manner as to be rotatable about an axis. The pulse motor rotates the ball screw about the axis. The guide rails of the X-axis direction moving unit 71 support the X-axis direction movable plate 14 movably in the X-axis direction. The guide rails of the X-axis direction moving unit 71 are fixed to the Y-axis direction movable plate 15. The guide rails of the Y-axis direction moving unit 72 support the Y-axis direction movable plate 15 movably in the Y-axis direction. The guide rails of the Y-axis direction moving unit 72 are fixed to the apparatus main body 2. The guide rails of the Z-axis direction moving unit 73 support the processing unit 20 and the vibration detecting unit 30 movably in the Z-axis direction. The guide rails of the Z-axis direction moving unit 73 are fixed to the column 3.

The display unit 80 is a display section constituted by a liquid crystal display device or the like. The display unit 80, for example, displays, on a display surface thereof, the interference pattern images 120 and 130 (see FIG. 4, FIG. 5, FIG. 6, and FIG. 7) captured by the imaging unit 50 of the vibration detecting unit 30, a processing condition setting screen, a state of the workpiece 100 imaged by the alignment unit 60, a state of a processing operation, and the like. In a case where the display surface of the display unit 80 includes a touch panel, the display unit 80 may include an input unit. The input unit can receive various kinds of operations including registration of processing content information by an operator and the like. The input unit may be an external input device such as a keyboard. Information or an image displayed on the display surface of the display unit 80 is changed by an operation from the input unit or the like. The display unit 80 may include a notifying device. The notifying device notifies the operator of the processing apparatus 1 of predetermined notification information by emitting at least one of sound and light. The notifying device may be an external notifying device such as a speaker or a light emitting device.

The control unit 90 makes the processing apparatus 1 perform a processing operation on the workpiece 100 by controlling each of the above-described constituent elements of the processing apparatus 1. In addition, the control unit 90 makes the processing apparatus 1 perform a detecting operation of detecting vibration of the processing apparatus 1. The control unit 90 controls the processing unit 20, the vibration detecting unit 30, the alignment unit 60, the X-axis direction moving unit 71, the Y-axis direction moving unit 72, the Z-axis direction moving unit 73, and the display unit 80.

The control unit 90 is a computer including an arithmetic processing device as arithmetic means, a storage device as storing means, and an input-output interface device as communicating means. The arithmetic processing device, for example, includes a microprocessor such as a central processing unit (CPU). The storage device has a memory such as a read only memory (ROM) and a random access memory (RAM). The arithmetic processing device performs various kinds of operations on the basis of a predetermined program stored in the storage device. The arithmetic processing device controls the processing apparatus 1 by outputting various kinds of control signals to the above-described constituent elements via the input-output interface device according to results of the operations.

The control unit 90, for example, makes the light source 33 of the vibration detecting unit 30 emit the light 51. The control unit 90, for example, makes the imaging unit 50 of the vibration detecting unit 30 capture interference pattern images 120 (see FIG. 4 and FIG. 5) including an interference pattern of the measurement target member (for example, the workpiece 100). In a case where the measurement target member (the workpiece 100) has a target pattern 140 on the inspection target surface (the top surface 101), the control unit 90 may, for example, make the imaging unit 50 capture interference pattern images 130 (see FIG. 6 and FIG. 7) including the target pattern 140. The control unit 90 illustrated in FIG. 1 includes a storage section 91, a comparing section 92, a vibration detecting section 93, and a three-dimensional image generating section 94.

The storage section 91 stores the interference pattern images 120 captured by the imaging unit 50. The storage section 91, for example, stores a first interference pattern image 121 illustrated in FIG. 4 which is captured at a predetermined timing by the imaging unit 50 and a second interference pattern image 122 illustrated in FIG. 5 which is captured at a timing different from that of the first interference pattern image 121.

FIG. 4 is a diagram illustrating an example of the first interference pattern image 121 captured at the predetermined timing. FIG. 5 is a diagram illustrating an example of the second interference pattern image 122 captured at the timing different from that of FIG. 4. The first interference pattern image 121 and the second interference pattern image 122 are images captured by the imaging unit 50 in a state in which the X-, Y-, and Z-axes are fixed.

The interference pattern images 120 include an interference pattern generated by interference between the reference light 52 and the reflected light 53 reflected by the measurement target member (the workpiece 100). The interference pattern images 120 captured by the imaging unit 50 have a luminance distribution based on a two-dimensional light intensity distribution of the interference light between the reference light 52 and the reflected light 53 imaged by the imaging element. In the interference pattern images 120, a region of high luminance is indicated in white. In the interference pattern images 120, a region of low luminance is indicated in black.

The comparing section 92 compares the first interference pattern image 121 and the second interference pattern image 122 stored in the storage section 91 with each other. For example, the first interference pattern image 121 illustrated in FIG. 4 and the second interference pattern image 122 illustrated in FIG. 5 each have a luminance distribution exhibiting a vertical stripe pattern. However, the positions of high-luminance regions and low-luminance regions in the first interference pattern image 121 and those in the second interference pattern image 122 are shifted from each other in the horizontal direction. That is, the comparing section 92 compares the first interference pattern image 121 and the second interference pattern image 122 with each other on the basis of the luminance distributions of the interference pattern images 120.

The vibration detecting section 93 detects vibration on the basis of the first interference pattern image 121 and the second interference pattern image 122 which have been compared with each other by the comparing section 92. That is, the luminance distributions of the interference pattern images 120 captured by the imaging unit 50 change according to the relative positions of the vibration detecting unit 30 and the holding unit 10 or the like. Hence, the vibration detecting section 93 detects vibration in the Z-axis direction on the basis of a difference between the luminance distribution of the first interference pattern image 121 and the luminance distribution of the second interference pattern image 122 which images have been compared with each other by the comparing section 92.

Description will next be made of a case where the measurement target member (the workpiece 100) has the target pattern 140 on the inspection target surface (the top surface 101). FIG. 6 is a diagram illustrating an example of a first interference pattern image 131 captured at a predetermined timing. FIG. 7 is a diagram illustrating an example of a second interference pattern image 132 captured at a timing different from that of FIG. 6. The first interference pattern image 131 and the second interference pattern image 132 are images captured by the imaging unit 50 in a state in which the X-, Y-, and Z-axes are fixed.

The storage section 91 stores the interference pattern images 130 including the target pattern 140 which images are captured by the imaging unit 50. The storage section 91, for example, stores the first interference pattern image 131 illustrated in FIG. 6 which is captured at the predetermined timing by the imaging unit 50 and the second interference pattern image 132 illustrated in FIG. 7 which is captured at the timing different from that of the first interference pattern image 131.

The comparing section 92 compares the first interference pattern image 131 and the second interference pattern image 132 stored in the storage section 91 with each other. For example, the position of the target pattern 140 in the first interference pattern image 131 illustrated in FIG. 6 and that in the second interference pattern image 132 illustrated in FIG. 7 are shifted from each other. That is, the comparing section 92 compares the first interference pattern image 131 and the second interference pattern image 132 with each other on the basis of the positions of the target patterns 140 in the interference pattern images 130.

The position of the target pattern 140 in the interference pattern images 130 captured by the imaging unit 50 changes according to the position in the X-Y plane direction of the vibration detecting unit 30. Hence, the vibration detecting section 93 detects vibration in the X-Y plane direction on the basis of a difference in position between the target pattern 140 in the first interference pattern image 131 and the target pattern 140 in the second interference pattern image 132 which images have been compared with each other by the comparing section 92.

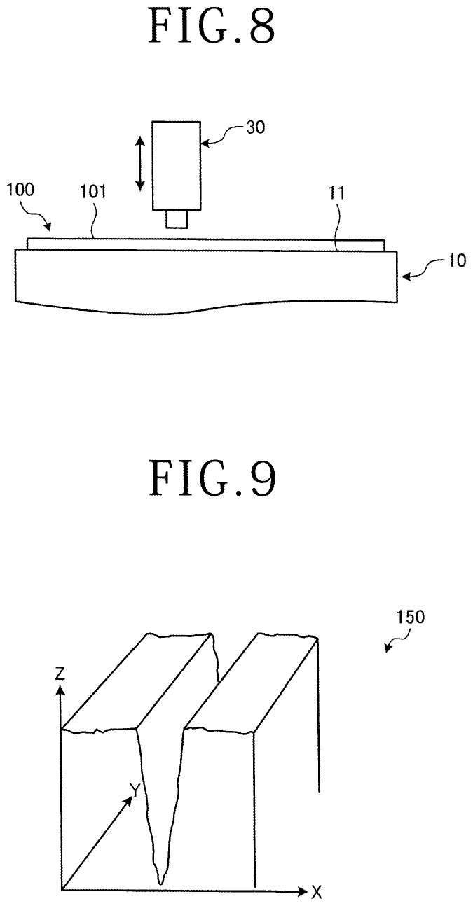

The three-dimensional image generating section 94 of the control unit 90 illustrated in FIG. 1 generates a three-dimensional image 150 of the measurement target member (for example, the workpiece 100). FIG. 8 is a schematic diagram illustrating a state in which interference pattern images to be used to obtain the three-dimensional image 150 are being captured. FIG. 9 is a diagram illustrating an example of the three-dimensional image 150 generated on the basis of the interference pattern images captured in FIG. 8.

In order to generate the three-dimensional image 150, first, as illustrated in FIG. 8, the imaging unit 50 captures a plurality of interference pattern images while the position of the imaging unit 50 is changed in a direction parallel with the imaging direction, that is, the Z-axis direction. At this time, the imaging unit 50 captures the plurality of interference pattern images in a state in which the X- and Y-axes are fixed. The three-dimensional image generating section 94 generates the three-dimensional image 150 of the measurement target member (for example, the workpiece 100) on the basis of the plurality of interference pattern images captured while the position of the imaging unit 50 is changed in the direction parallel with the imaging direction, that is, the Z-axis direction.

Incidentally, in the embodiment, for example, a plurality of three-dimensional images 150 generated on the basis of different interference pattern images may be compared with each other, and vibration may be detected on the basis of differences in depth, shape, and the like between the three-dimensional images 150.

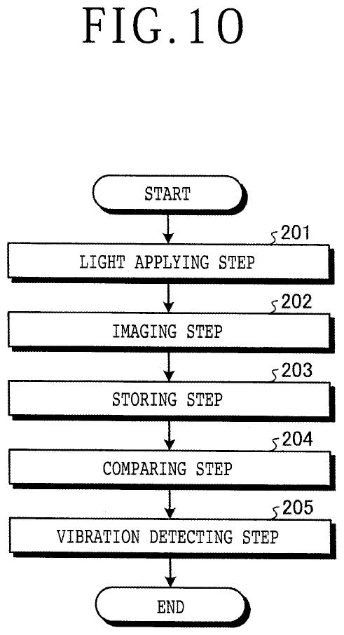

A vibration detecting method according to the embodiment will next be described. FIG. 10 is a flowchart diagram illustrating a flow of the vibration detecting method according to the embodiment. As illustrated in FIG. 10, the vibration detecting method includes a light applying step 201, an imaging step 202, a storing step 203, a comparing step 204, and a vibration detecting step 205.

The light applying step 201 is a step of irradiating the measurement target member (for example, the holding unit 10 or the workpiece 100) with the light 51. In the light applying step 201 in the embodiment, the control unit 90 illustrated in FIG. 1 makes the light source 33 of the vibration detecting unit 30 emit the light 51. The light 51 emitted from the light source 33 is reflected by the half-silvered mirror 34 toward the measurement target member disposed on the lower side (see FIG. 2). The light 51 passes through the condensing unit 35 and the plate 41 and is thereafter branched into two light fluxes by the half-silvered mirror 42.

One light flux of the two branched light fluxes passes through the half-silvered mirror 42, is reflected by the measurement target member (for example, the holding unit 10 or the workpiece 100), passes through the half-silvered mirror 42, the plate 41, the condensing unit 35, and the half-silvered mirror 34 as the reflected light 53, and enters the imaging unit 50. The other light flux is reflected upward by the half-silvered mirror 42, is reflected downward by the reference mirror 43, is reflected upward by the half-silvered mirror 42 again as the reference light 52, then passes through the plate 41, the condensing unit 35, and the half-silvered mirror 34, and enters the imaging unit 50.

The imaging step 202 is a step of capturing interference pattern images 120 and 130 including an interference pattern generated by interference between the reflected light 53 obtained by the light 51 being branched into two light fluxes and one light flux of them being reflected by the measurement target member (for example, the holding unit 10 or the workpiece 100) and the reference light 52 generated from the other light flux.

In the imaging step 202 in the embodiment, the control unit 90 illustrated in FIG. 1 makes the imaging unit 50 capture interference pattern images 120 and 130 including the interference pattern of the measurement target member (for example, the workpiece 100). In a case where the measurement target member (the workpiece 100) has the target pattern 140 on the inspection target surface (the top surface 101), the imaging step 202 captures interference pattern images 130 including the target pattern 140.

The storing step 203 is a step of storing the interference pattern images 120 and 130 captured in the imaging step 202. In the storing step 203 in the embodiment, the storage section 91 of the control unit 90 illustrated in FIG. 1 stores the first interference pattern images 121 and 131 and the second interference pattern images 122 and 132 captured by the imaging unit 50.

The comparing step 204 is a step of comparing the first interference pattern images 121 and 131 captured at a predetermined timing with the second interference pattern images 122 and 132 captured at a timing different from that of the first interference pattern images 121 and 131. In the comparing step 204 in the embodiment, the comparing section 92 of the control unit 90 illustrated in FIG. 1 compares the luminance distributions of the first interference pattern images 121 and 131 with the luminance distributions of the second interference pattern images 122 and 132.

In a case where the measurement target member (the workpiece 100) has the target pattern 140 on the inspection target surface (the top surface 101) and the imaging step 202 captures the interference pattern images 130 including the target pattern 140, the comparing step 204 in the embodiment compares the position of the target pattern 140 in the interference pattern images 130. More specifically, the comparing section 92 further compares the position of a first target pattern 140 in the first interference pattern image 131 captured at the predetermined timing with the position of a second target pattern 140 in the second interference pattern image 132 captured at the timing different from that of the first interference pattern image 131.

The vibration detecting step 205 is a step of detecting vibration on the basis of the first interference pattern images 121 and 131 and the second interference pattern images 122 and 132 compared in the comparing step 204. In the vibration detecting step 205 in the embodiment, the vibration detecting section 93 of the control unit 90 illustrated in FIG. 1 detects vibration on the basis of the first interference pattern images 121 and 131 and the second interference pattern images 122 and 132 compared with each other by the comparing section 92.

That is, the luminance distributions of the interference pattern images 120 and 130 captured in the imaging step 202 change according to the relative positions of the vibration detecting unit 30 and the holding unit 10 or the like. Hence, the vibration detecting step 205 detects vibration in the Z-axis direction on the basis of a difference between the luminance distribution of the first interference pattern image 121 and the luminance distribution of the second interference pattern image 122 which images have been compared with each other by the comparing section 92.

In addition, the position of the target pattern 140 in the interference pattern images 130 captured in the imaging step 202 changes according to the position in the X-Y plane direction of the vibration detecting unit 30. Hence, the vibration detecting step 205 detects vibration in the X-Y plane direction on the basis of a difference in position between the target pattern 140 in the first interference pattern image 131 and the target pattern 140 in the second interference pattern image 132 which images have been compared with each other in the comparing step 204.

As described above, the processing apparatus 1 and the vibration detecting method according to the embodiment observe a change in the interference pattern of the reflected light 53 reflected by the measurement target member (for example, the holding unit 10 or the workpiece 100) which interference pattern is caused by the reference light 52 generated by the interference unit 40, the reflected light 53 and the reference light 52 being two light fluxes branched from the light 51 emitted from the light source 33. The processing apparatus 1 and the vibration detecting method can capture the interference pattern images 120 and 130 including the interference pattern and detect vibration in the Z-axis direction from the difference between the first interference pattern images 121 and 131 and the second interference pattern images 122 and 132 captured at different timings.

Hence, it is possible to detect vibration of the processing apparatus 1 in the height direction of the workpiece 100, which is to be processed on the processing apparatus 1, thus producing an advantageous effect of facilitating determining a cause of the vibration and identifying and improving a part causing the vibration. That is, because a change between vibration states before and after relocation (shipment) of the processing apparatus 1 or the like can be confirmed, determination can be made as to whether the vibration is caused by an environment factor such as a building or by the processing apparatus 1 itself.

Further, vibration not only in the Z-axis direction but also in the X-Y plane direction can be detected on the basis of movement in the X-Y plane direction of the interference pattern images 120 and 130. Thus, vibration in three axial directions can be detected at the same time.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus comprising:
a holding unit configured to hold a workpiece;
a processing unit configured to process the workpiece held by the holding unit;
a moving unit configured to move the holding unit and the processing unit relative to each other;
a vibration detecting unit; and
a control unit configured to control the holding unit, the processing unit, the moving unit, and the vibration detecting unit;
the vibration detecting unit including
a light source,
an interference unit configured to apply light emitted from the light source to a measurement target member and generate an interference pattern image including an interference pattern of the measurement target member, and
an imaging unit configured to capture the interference pattern image of the measurement target member, the interference pattern image being generated by the interference unit;
the control unit including
a storage section configured to store a first interference pattern image captured at a predetermined timing by the imaging unit and a second interference pattern image captured at a timing different from the timing of the first interference pattern image by the imaging unit,
a comparing section configured to compare the first interference pattern image and the second interference pattern image stored in the storage section with each other, and
a vibration detecting section configured to detect vibration on a basis of the first interference pattern image and the second interference pattern image compared with each other by the comparing section.

2. The processing apparatus according to claim 1, wherein
the control unit further includes a three-dimensional image generating section configured to generate a three-dimensional image of the measurement target member on a basis of a plurality of interference pattern images captured while a position of the imaging unit is changed in a direction parallel with an imaging direction.

3. The processing apparatus according to claim 1, wherein
the measurement target member is the holding unit configured to hold the workpiece.

4. A vibration detecting method for detecting vibration, the vibration detecting method comprising:
a light applying step of irradiating a measurement target member with light;
an imaging step of capturing an interference pattern image including an interference pattern generated by interference between reflected light obtained by the light being branched into two light fluxes and one light flux of the two branched light fluxes being reflected by the measurement target member and reference light generated from the other light flux;
a storing step of storing the interference pattern image captured in the imaging step;
a comparing step of comparing a first interference pattern image captured at a predetermined timing with a second interference pattern image captured at a timing different from the timing of the first interference pattern image; and
a vibration detecting step of detecting vibration on a basis of the first interference pattern image and the second interference pattern image compared with each other in the comparing step.

5. The vibration detecting method according to claim 4, wherein
the measurement target member has a target pattern,
the imaging step captures an interference pattern image including the target pattern, and
the comparing step further compares a position of a first target pattern in the first interference pattern image captured at the predetermined timing with a position of a second target pattern in the second interference pattern image captured at the timing different from the timing of the first interference pattern image.
